(19) United States
(12) Patent Application Publication
(10) Pub. No.: US 2026/0371565 A1
(43) Pub. Date: Nov. 19, 2026

(54) MICROELECTRONIC DEVICES INCLUDING VERTICAL CHANNEL ACCESS DEVICES, AND RELATED METHODS AND MEMORY DEVICES

(71) Applicant: Micron Technology, Inc., Boise, ID (US)

(72) Inventors: Devanarayanan Perinthatta Ettisserry, Boise, ID (US); Marcello Mariani, Milano (IT); Kamal M. Karda, Boise, ID (US)

(21) Appl. No.: 19/659,397

(22) Filed: Apr. 27, 2026

Related U.S. Application Data
(60) Provisional application No. 63/804,851, filed on May 13, 2025.

(51) Int. Cl. H10B 12/00

(52) U.S. Cl. CPC H10B 12/33; H10B 12/05

(57) ABSTRACT

A microelectronic device including a vertical channel access device (VCAD) that includes a semiconductor pillar having a first doped region, a channel region above the first doped region, and a second doped region above the channel region. The VCAD includes a gate electrode horizontally offset from the semiconductor pillar and vertically overlapping the channel region. The VCAD includes gate dielectric material horizontally interposed between the gate electrode and the semiconductor pillar. The microelectronic device includes a first liner structure extending in a first direction and neighboring the semiconductor pillar in a second direction. The microelectronic device includes a second liner structure vertically offset from, in physical contact, and horizontally overlapping the first liner structure. The microelectronic device includes a digit line structure vertically offset from and substantially horizontally centered about the semiconductor pillar, and in physical contact with the second liner structure and the first doped region.

### CROSS-REFERENCE TO RELATED APPLICATIONS

This application claims the benefit under 35 U.S.C. § 119(e) of U.S. Provisional Patent Application Ser. No. 63/804,851, filed May 13, 2025, the disclosure of which is hereby incorporated herein in its entirety by this reference.

### TECHNICAL FIELD

This disclosure, in various embodiments, relates generally to the field of microelectronic device design and fabrication. More specifically, the disclosure relates to methods of forming microelectronic devices from independently formed microelectronic device structures, and to related microelectronic devices and electronic systems.

### BACKGROUND

One example of a microelectronic device is a memory device. Memory devices are generally provided as internal integrated circuits in computers or other electronic devices. There are many types of memory devices including, but not limited to, volatile memory devices, such as dynamic random-access memory (DRAM) devices; and non-volatile memory devices such as NAND Flash memory devices. A typical memory cell of a DRAM device includes one access device, such as a transistor, and one memory storage structure, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines (e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D) so as to exhibit multiple decks (e.g., multiple levels, multiple tiers) of the memory cells.

As the density and complexity of the memory array have increased, so has the complexity of the memory devices. In some instances, horizontally oriented access devices (e.g., horizontal channel access devices) for memory cells of a memory device consume more horizontal real estate within the memory device than is desirable, reducing the memory density of the memory device.

### BRIEF DESCRIPTION OF THE DRAWINGS

FIGS. 1A through 1Q illustrate simplified, vertical-cross-sectional views of a microelectronic device structure at different processing stages of a method of forming a microelectronic device, according to one or more embodiments of the disclosure.

FIGS. 1R and 1S illustrate simplified, perspective views of a microelectronic device structure at different processing stages of a method of forming a microelectronic device, according to one or more embodiments of the disclosure.

FIG. 2 is a schematic block diagram of an electronic system, in accordance with an embodiment of the disclosure.

### DETAILED DESCRIPTION

The illustrations included herewith are not meant to be actual views of any particular systems, microelectronic structures, microelectronic devices, or integrated circuits thereof, but are merely idealized representations that are employed to describe embodiments herein. Elements and features common between figures may retain the same numerical designation except that, for ease of following the description, reference numerals begin with the number of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device), apparatus, or electronic system, or a complete microelectronic device, apparatus, or electronic system. The structures described below do not form a complete microelectronic device, apparatus, or electronic system. Only those process acts and structures necessary to understand the embodiments described herein are described in detail below. Additional acts to form a complete microelectronic device, apparatus, or electronic system from the structures may be performed by conventional techniques.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “longitudinal,” “vertical,” “lateral,” and “horizontal” are in reference to a major plane of a substrate (e.g., base material, base structure, base construction, etc.) in or on which one or more structures and/or features are formed and are not necessarily defined by Earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “proximate,” when utilized to describe positions of elements relative to each other, means that the elements are relatively close or near to each other. For example, where a first element is proximate a horizontal boundary of a second element, the first element is closer to that horizontal boundary than other horizontal boundaries of the second element.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “memory device” means and includes microelectronic devices exhibiting memory functionality but not necessarily limited to memory functionality. Stated another way, and by way of example only, the term “memory device” means and includes not only conventional memory (e.g., conventional volatile memory, such as conventional DRAM; conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe-and Ni-based alloy, a Co-and Ni-based alloy, an Fe-and Co-based alloy, a Co-and Ni-and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively doped polysilicon, conductively doped germanium (Ge), conductively doped silicon germanium (SiGe)). In addition, a “conductive structure” means and includes a structure formed of and including a conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including an insulative material.

As used herein, the term “sacrificial material” means and includes a material that is formed and/or employed during a fabrication process, but which is subsequently removed, in whole or in part, prior to completion of the fabrication process. A “partially sacrificial” material means and includes a sacrificial material from which only one or more portions is or are removed prior to completion of the fabrication process. A “wholly sacrificial” material means and includes a sacrificial material that is substantially entirely removed prior to completion of the fabrication process.

As used herein, “semiconductor material” and “semiconductive material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

Unless the context indicates otherwise, the materials described herein may be formed by any suitable technique including, but not limited to, spin coating, blanket coating, chemical vapor deposition (CVD), plasma enhanced CVD (PECVD), atomic material deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

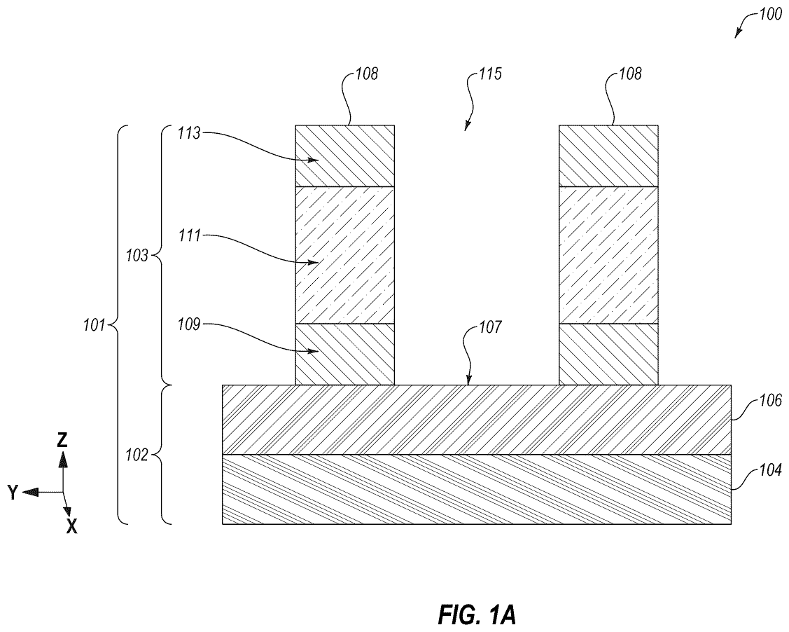

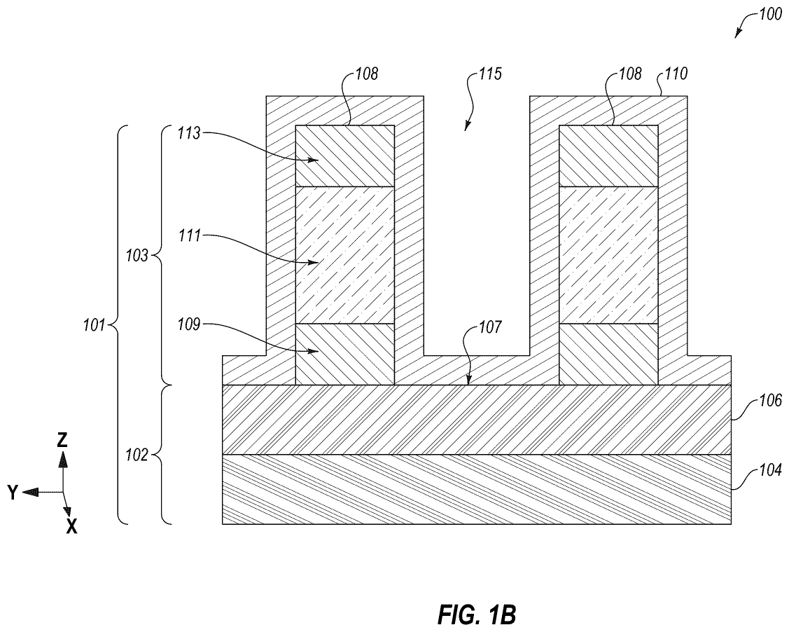

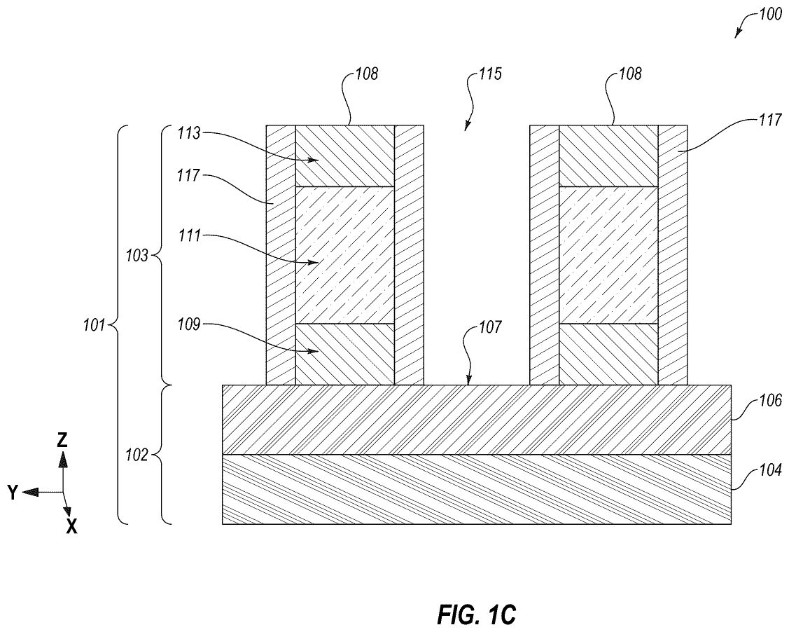

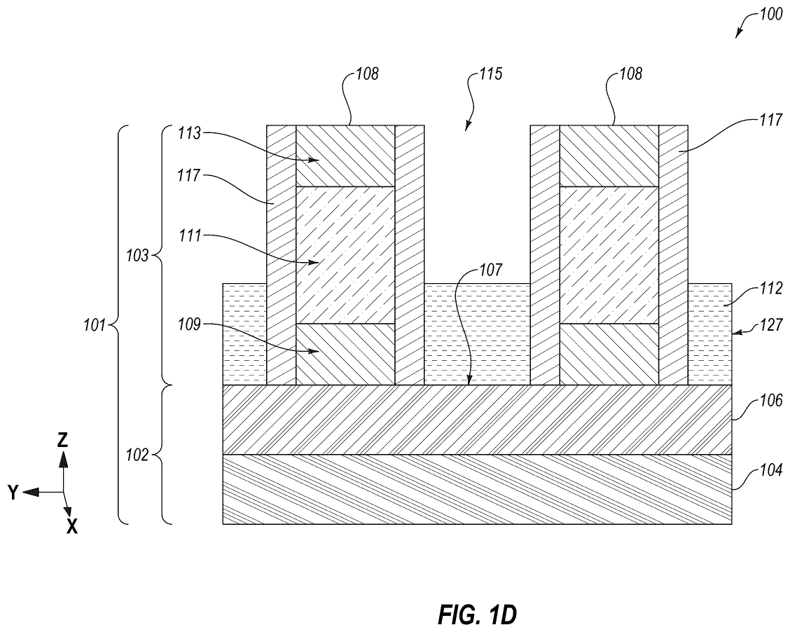

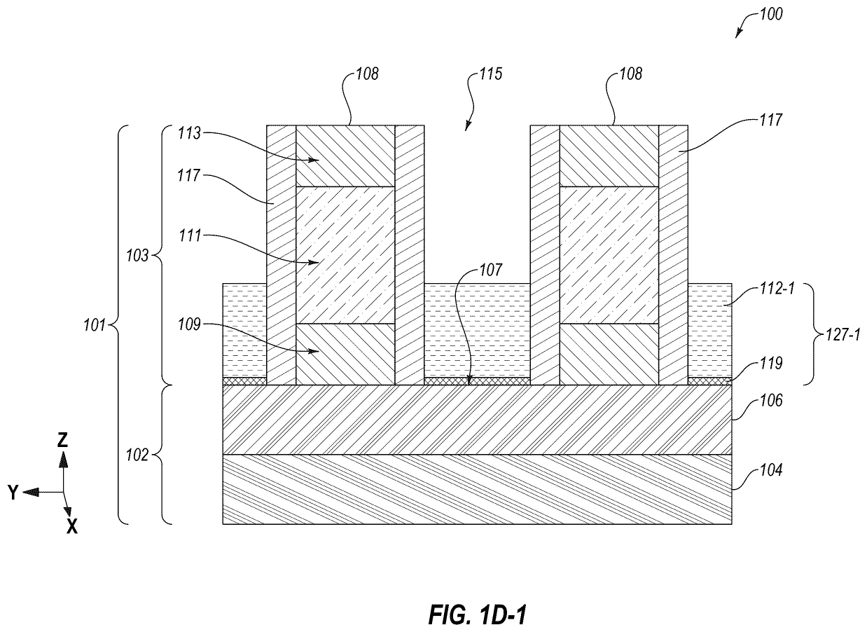

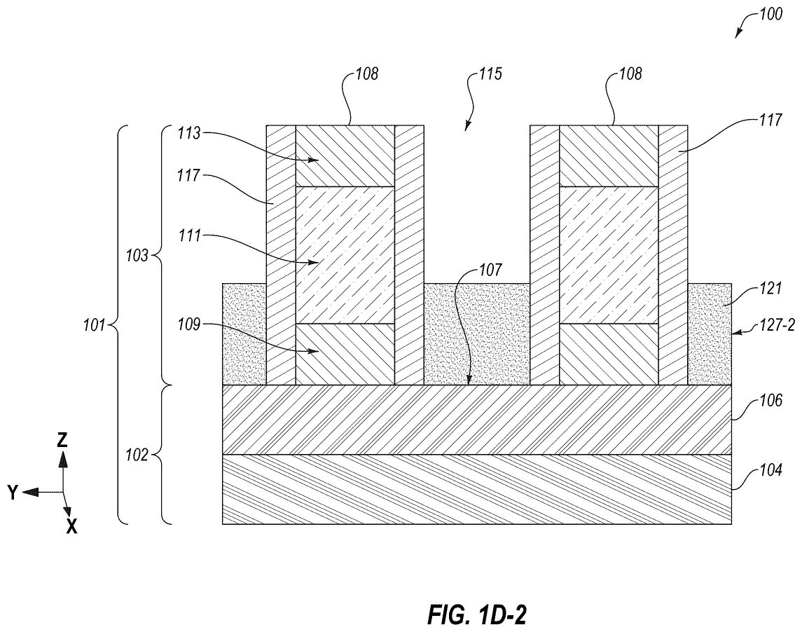

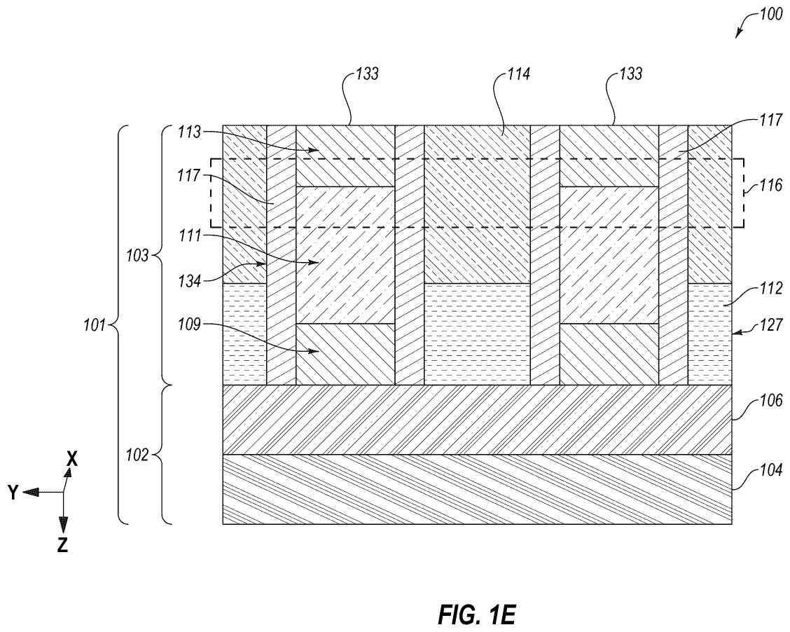

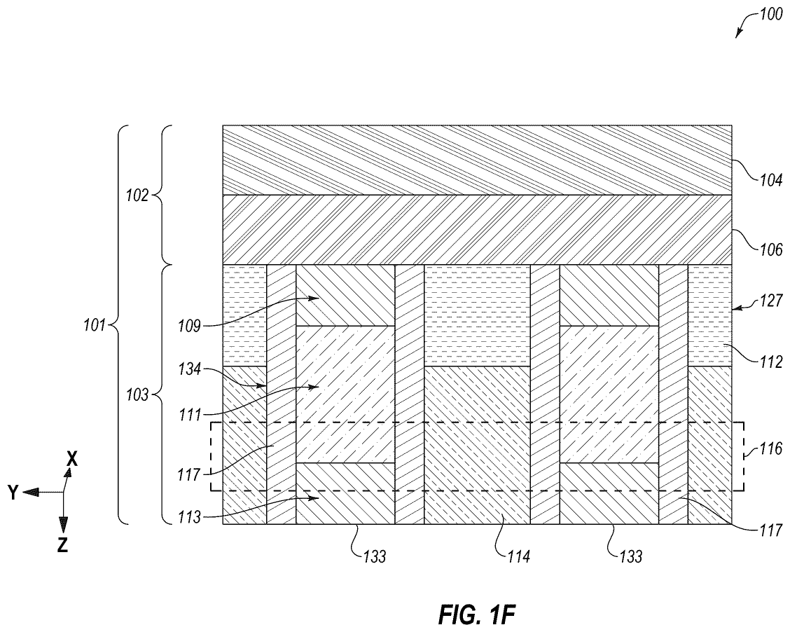

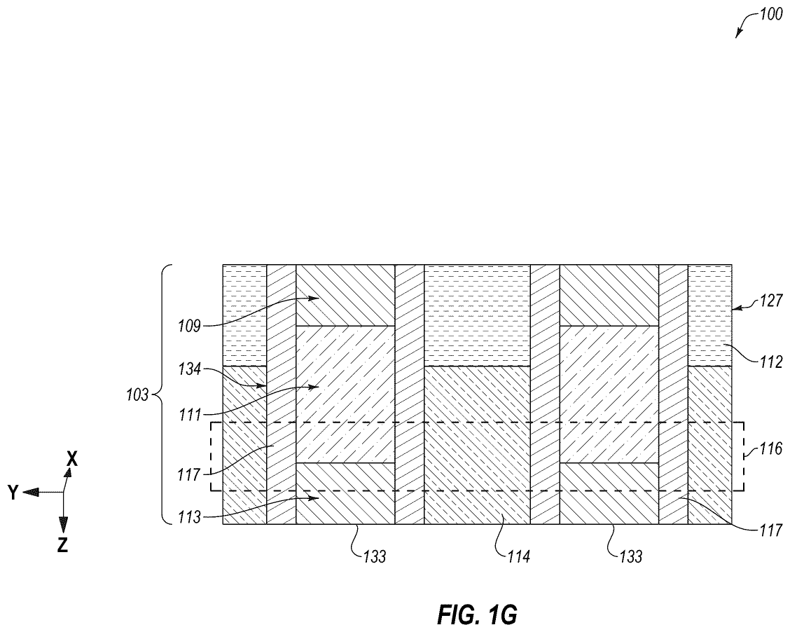

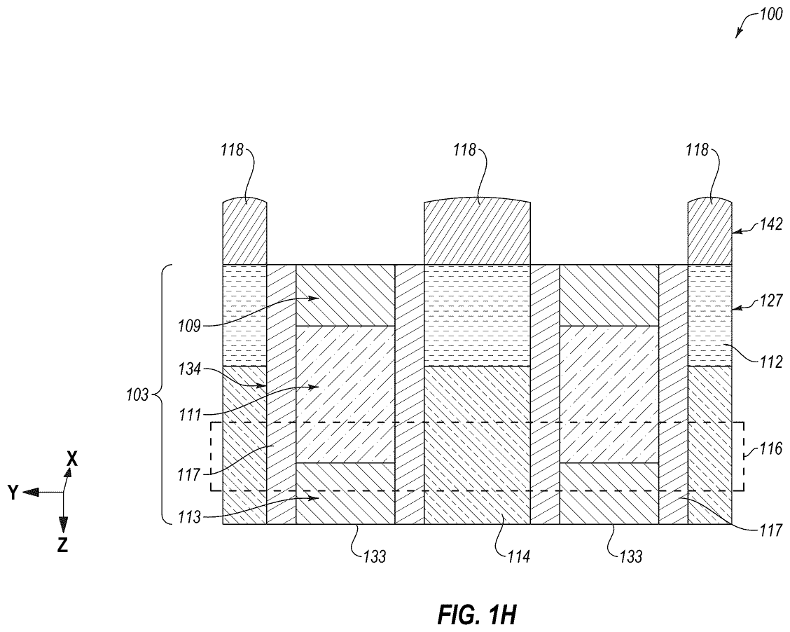

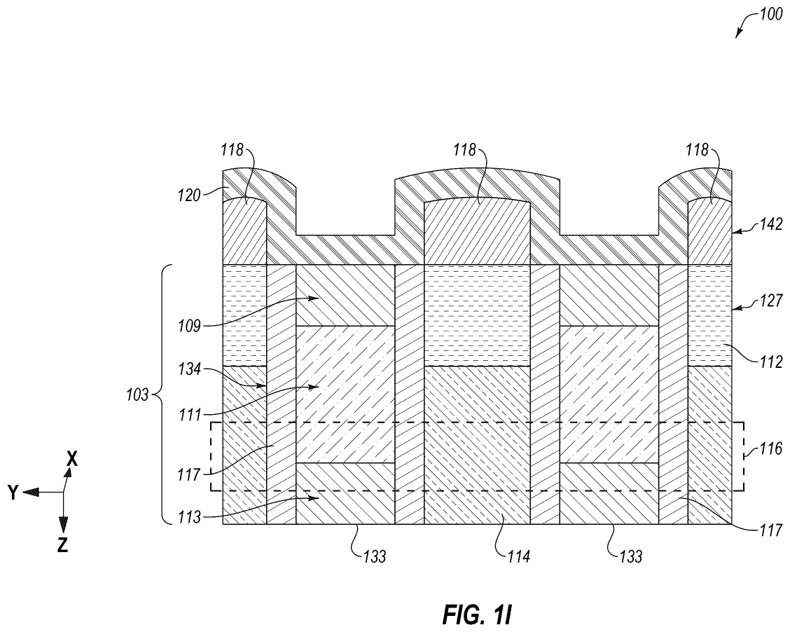

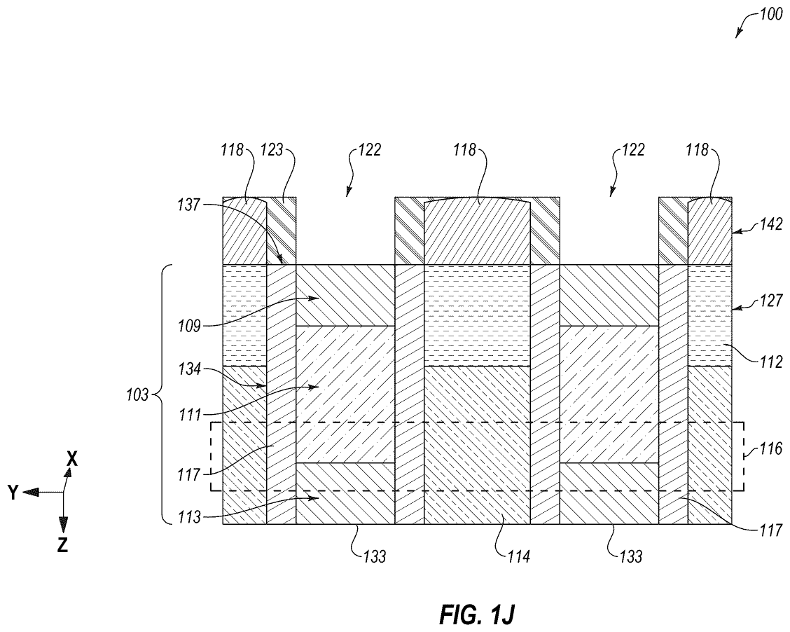

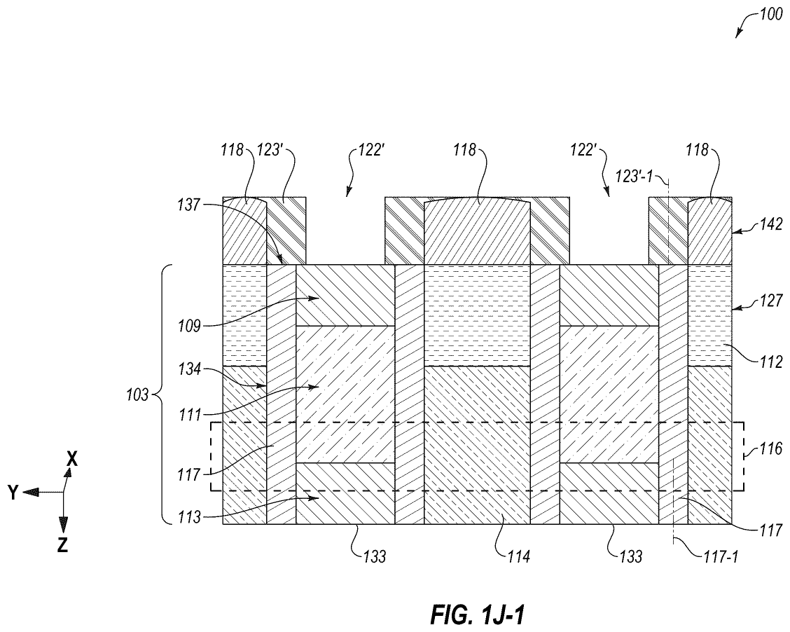

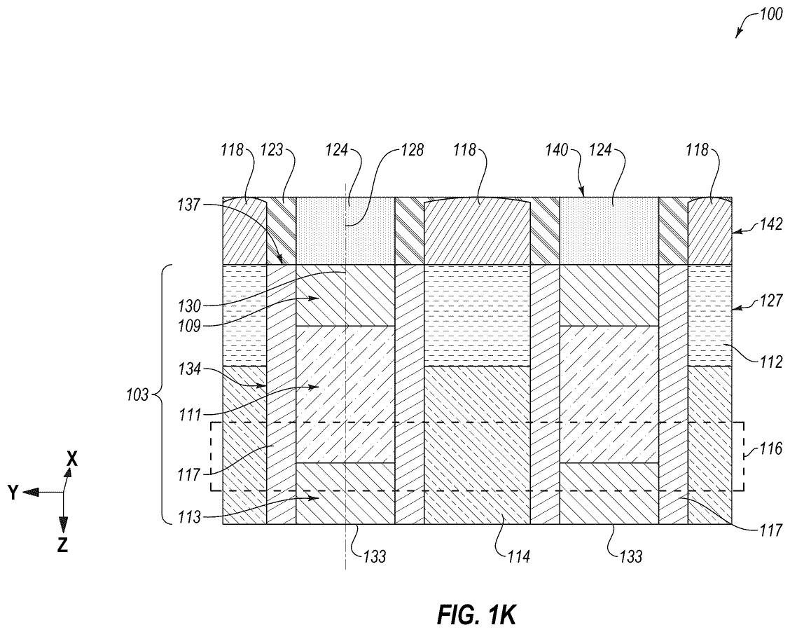

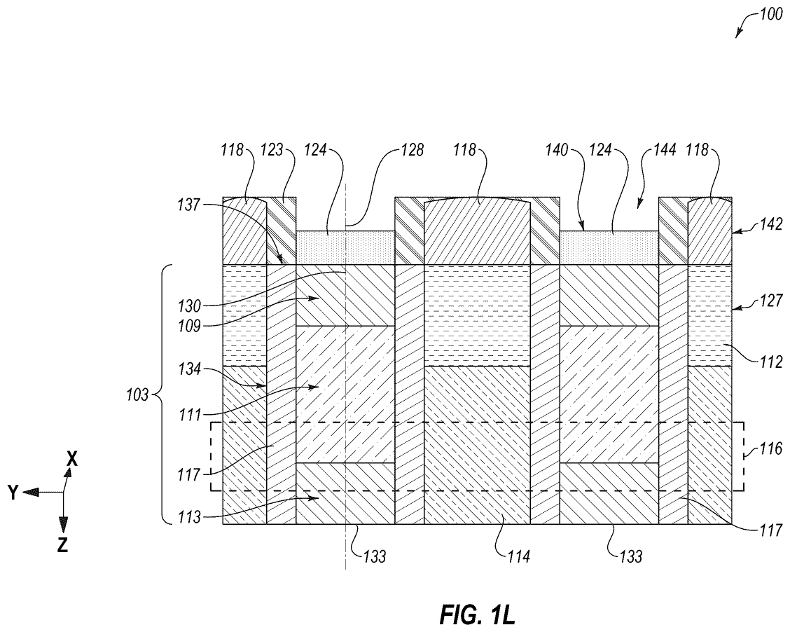

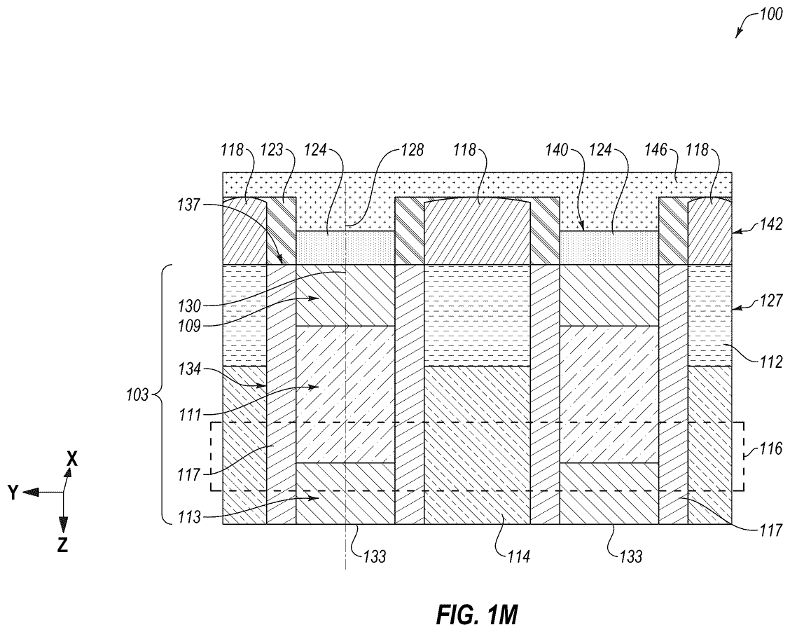

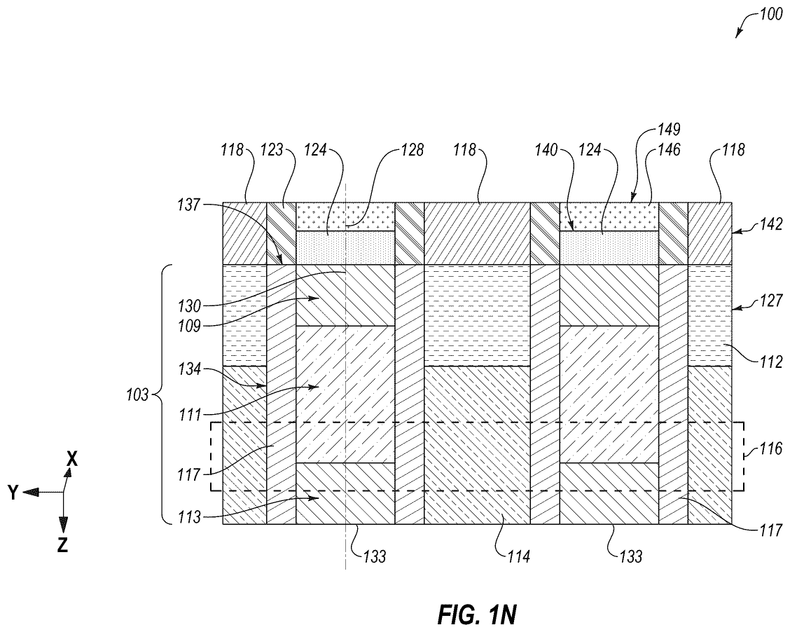

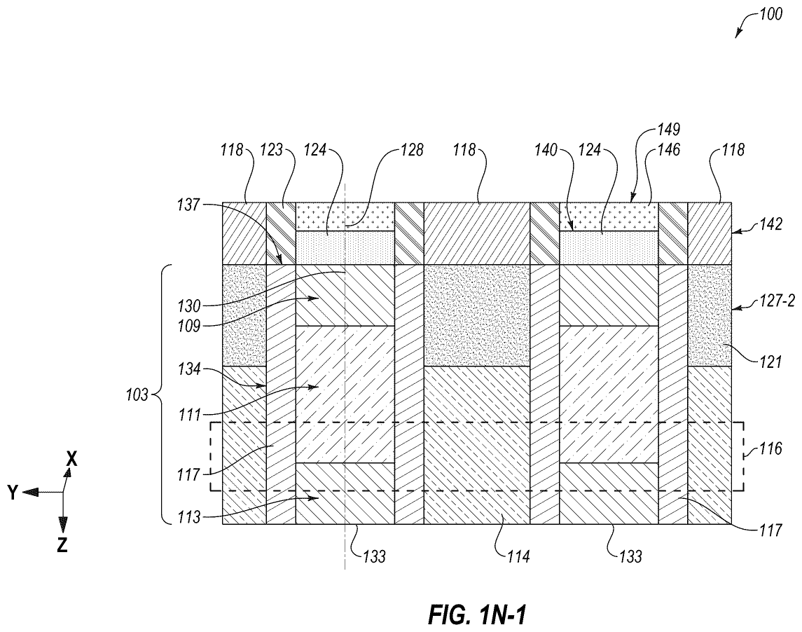

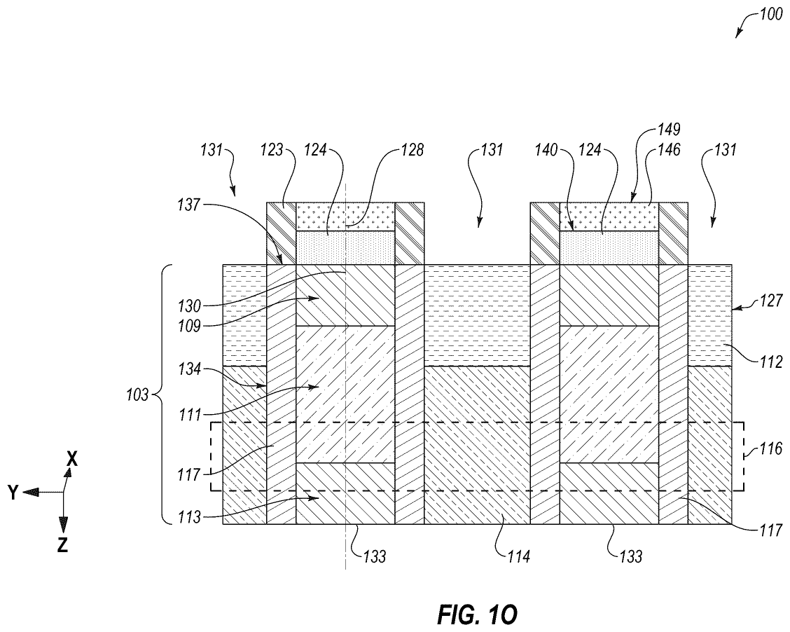

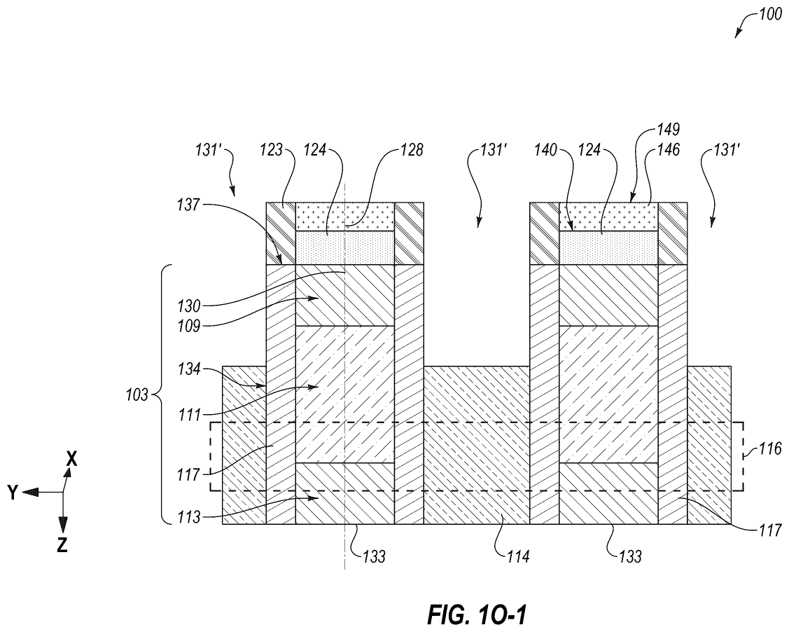

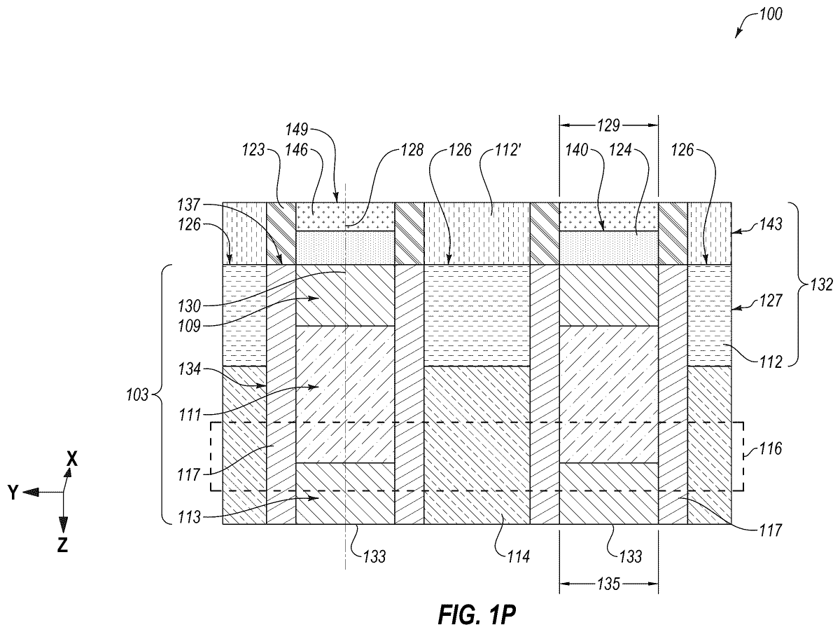

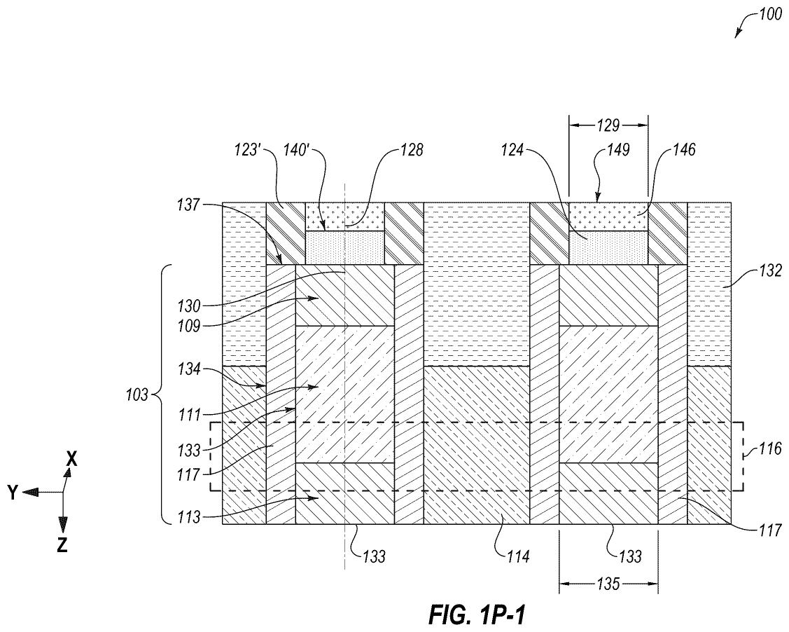

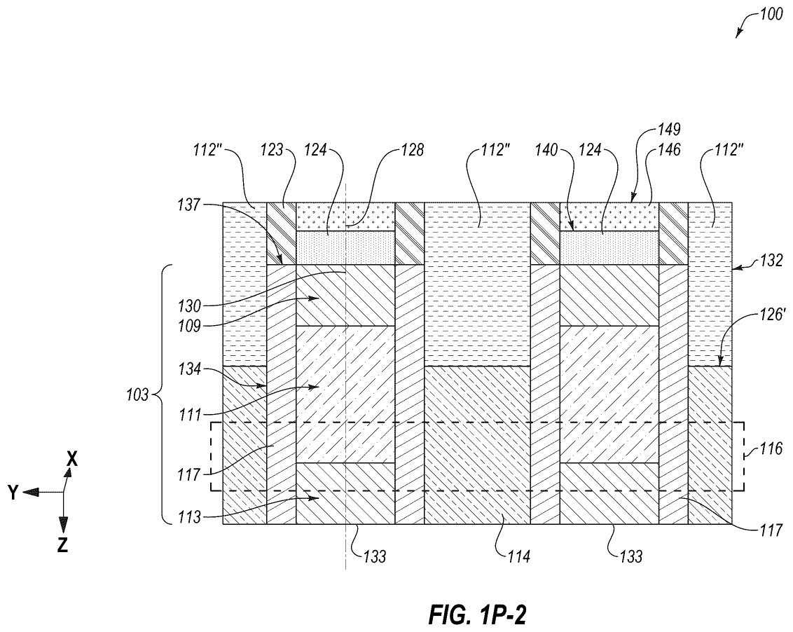

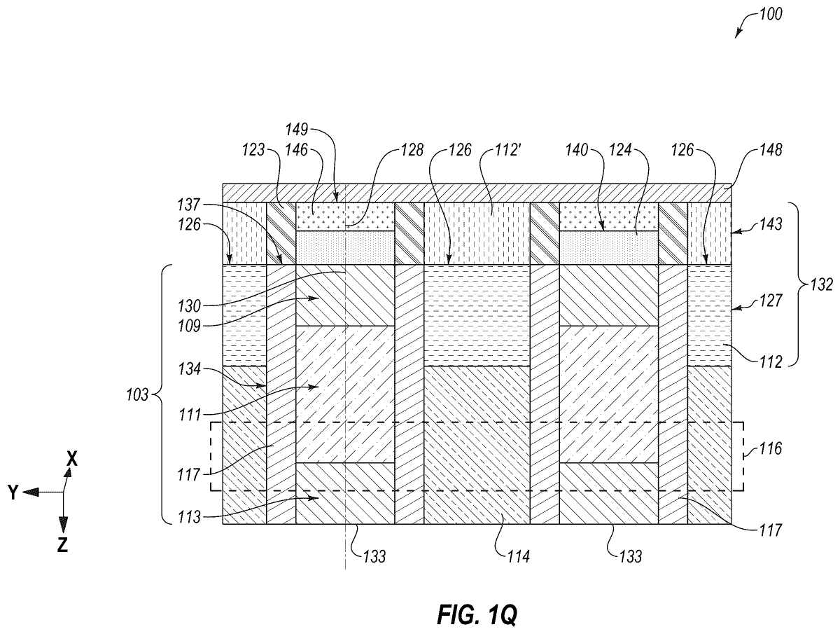

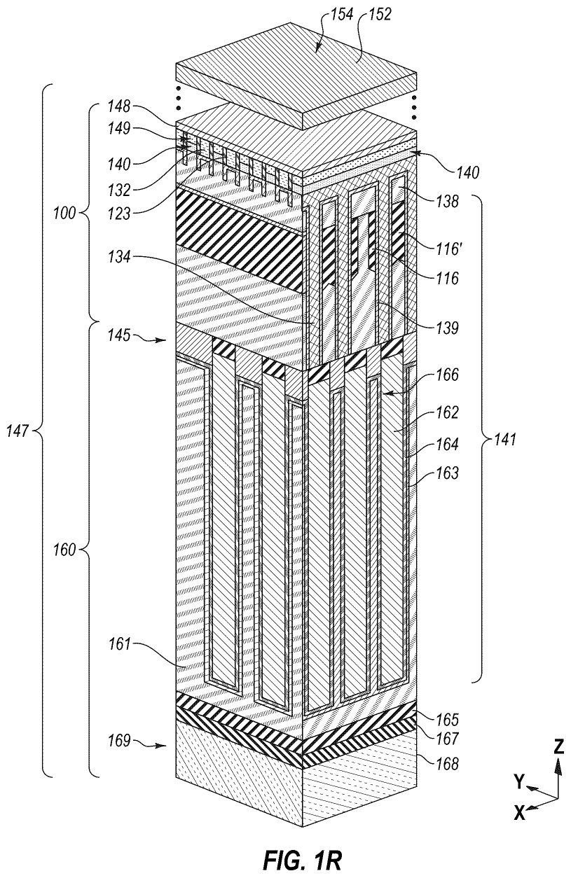

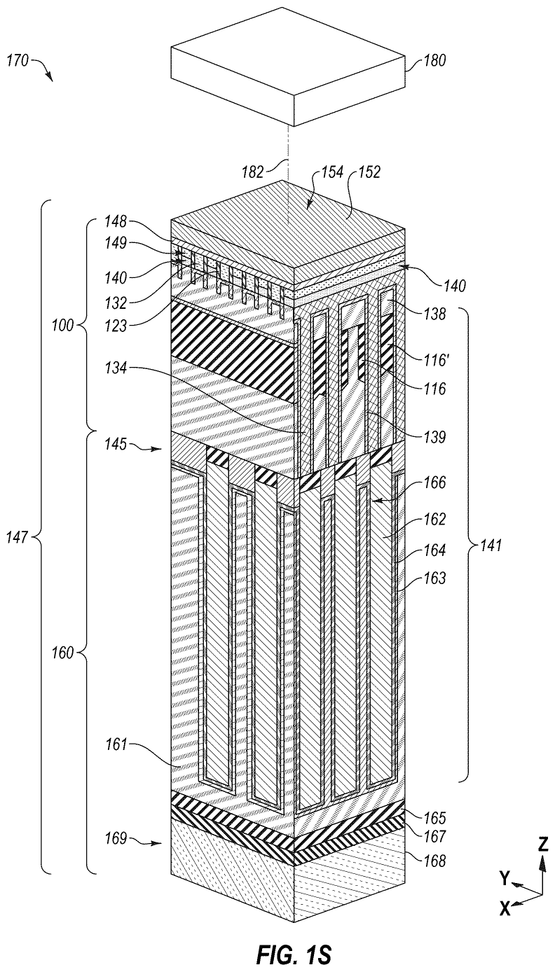

FIGS. 1A through 1Q illustrate simplified, vertical cross-sectional views of a microelectronic device structure 100 at different processing stages of a method of forming a microelectronic device (e.g., a memory device, such as a DRAM device, a holographic random-access memory (HRAM) device, a ferroelectric random-access memory (FeRAM) device, a synchronous dynamic random-access (SDRAM) device, a magnetoresistive (MRAM) device, or the like), in accordance with embodiments of the disclosure. With the description provided below, it will be readily apparent to one of ordinary skill in the art that the methods described herein may be used for forming various devices.

Referring to FIG. 1A, forming a microelectronic device structure 100 may include forming a first assembly 101. The first assembly 101 may also be referred to herein as a die or a wafer. The first assembly 101 may at least include a semiconductor material 103 (e.g., a semiconductor wafer), or a base semiconductive material on a support structure or construction upon which additional materials and structures of the microelectronic device structure 100 are formed. In some embodiments, the first assembly 101 also includes a base structure 102 (e.g., carrier wafer). The semiconductor material 103 is connected to the base structure 102. The base structure 102 includes a first base structure 104 (e.g., silicon substrate) and an insulative structure 106 formed on or over the first base structure 104. The semiconductor material 103 may be formed on or over the insulative structure 106. The insulative structure 106 may be an etch stop material (e.g., a semiconductive etch stop material, such as SiGe) that provides an etch stop barrier at a top surface 107 of the insulative structure 106. The semiconductor material 103 together with the insulative structure 106 may form a silicon-over-insulator (SOI) substrate.

The semiconductor material 103 may be formed of and include silicon material, such as epitaxial silicon material. The semiconductor material 103 may be formed as semiconductor lines 108. Additionally, the semiconductor material 103 may include a first doped region 109 vertically overlying the insulative structure 106 (or an etch stop material), an undoped region 111 vertically overlying the first doped region 109, and a second doped region 113 vertically overlying the undoped region 111. In some embodiments, each of the first doped region 109 and the second doped region 113 are N-type doped, such as N-type doped to an N-type dopant concentration within a range of from about 10¹⁵ cm⁻³ to about 10²⁰ cm⁻³. In additional embodiments, one of the first doped region 109 and the second doped region 113 may be N-type doped while the other of the first doped region 109 and the second doped region 113 may be P-type doped, such as P-type doped to a P-type dopant concentration within a range of from about −10¹³ cm⁻³ to about −10¹⁸ cm⁻³. In additional embodiments, one or more of the first doped region 109 and the second doped region 113 is doped (either P-doped or N-doped) to the point of saturation (e.g., greater than or equal to about −10¹⁸ cm⁻³). The doping may be accomplished utilizing any suitable processing, such as by implanting dopant (e.g., at least one N-type dopant or at least one P-type dopant) into the semiconductor material 103. A P-type dopant may include one or more of boron, aluminum, and gallium; and an N-type dopant may include one or more of arsenic, phosphorous, antimony, and bismuth.

In some embodiments, the undoped region 111 does not include any P-type dopants or any N-type dopants. In alternative embodiments, the undoped region 111 is doped with one of the dopants described herein and become another doped region. In such embodiments, a dopant type of the undoped region 111 is different than dopant types of the first doped region 109 and the second doped region 113. For example, if the first doped region 109 and the second doped region 113 respectively include semiconductor material (e.g., epitaxial silicon) doped with at least one N-type dopant, the undoped region 111 may include the semiconductor material (e.g., epitaxial silicon) doped with at least one P-type dopant.

As is discussed in further detail below, in some embodiments, the first doped region 109 forms a drain region of a later-formed vertical channel access device (VCAD) (e.g., vertical channel transistor (VCT)), the undoped region 111 forms a channel region of the later-formed VCAD, and the second doped region 113 forms a source region of the later-formed VCAD. The semiconductor lines 108 will be employed to form semiconductor pillars of the later formed VCT. The semiconductor lines 108 defined and horizontally separated (e.g., in the Y-direction) by first trenches 115 formed in the semiconductor material 103.

The first trenches 115 (e.g., first x-axis trenches) extending vertically into the first assembly 101 and the semiconductor material 103 of the microelectronic device structure 100. The first trenches 115 may extend horizontally in parallel in a first direction (e.g., the X-direction) and may be horizontally separated from one another in a second direction (e.g., the Y-direction) orthogonal to the first direction. The first trenches 115 may have any suitable dimensions. In some embodiments, the first trenches 115 have vertical depths (e.g., vertical heights in the Z-direction) within a range of from about 100 nm to about 200 nm (e.g., about 150 nm).

Referring to FIG. 1B, a dielectric liner 110 is formed (e.g., conformally formed) on the exposed surfaces (e.g., side surfaces, upper surfaces) of the semiconductor lines 108 and the insulative structure 106. The dielectric liner 110 may be formed of and include an insulative material. In some embodiments, the dielectric liner 110 is formed of and incudes an insulative material with a relatively high dielectric constant (k) (e.g., a high-k material) as compared to silicon dioxide, such as a dielectric constant greater than about 3.9 (e.g., greater than or equal to 4, such as greater than or equal to 10, greater than or equal to 20, or greater than or equal to 25). In some embodiments, the dielectric liner 110 is formed of and includes silicon nitride. The dielectric liner 110 may be formed (e.g., conformally deposited) inside and outside of the first trenches 115, onto exposed portions of the semiconductor lines 108 and the insulative structure 106.

Referring to FIG. 1C, an anisotropic etch may be performed to remove the portions (e.g., horizontally extending portions) of the dielectric liner 110 inside and outside of the first trenches 115 to form dielectric liner structures 117 located on side surfaces of the semiconductor lines 108 defining the first trenches 115.

Referring to FIG. 1D, preliminary structures 127 are formed within the first trenches 115. The preliminary structures 127 may partially (e.g., less than completely) fill the first trenches 115. The preliminary structures 127 may respectively be formed of and include conductive material 112. For example, the preliminary structures 127 may form a shield structure as discussed hereinbelow. The preliminary structures 127 may respectively be configured to enable a digit line alignment material 118 (FIG. 1H) to grow on a surface thereof after later removal of the base structure 102 for the later formation of self-aligned digit line structures 140 (FIG. 1K), as also discussed hereinbelow. In an embodiment, the conductive material 112 of the preliminary structures 127 includes one or more of Ti, W, Mo, Ru, TiN, and WN. In some embodiments, the conductive material 112 of the preliminary structures 127 includes a metal nitride material (e.g., titanium nitride, tungsten nitride). The preliminary structures 127 may individually have a vertical thickness within a range of from about 2 nm to about 10 nm.

Referring to FIG. 1D-1, in another embodiment, preliminary structures 127-1 are formed within the first trenches 115. The preliminary structures 127-1 may respectively include a seed material 119 and a conductive material 112-1 (e.g., titanium nitride) on or over the seed material 119. The seed material 119 may be relatively thin (e.g., have a smaller vertical thickness) as compared to the conductive material 112-1. In an embodiment, the seed material 119 has a vertical thickness of less than a quarter of the vertical thickness of the conductive material 112-1. In yet another embodiment, the seed material 119 has a vertical thickness of less than one tenth of the vertical thickness of the conductive material 112-1. In another embodiment, the seed material 119 has a vertical thickness of less than about five percent of the vertical thickness of the conductive material 112-1.

The seed material 119 may be configured to enable a digit line alignment material 118 (FIG. 1H) to grow on the surface of the seed material 119 after the later removal of the base structure 102 for the later formation of aligned digit line structures as discussed herein. In some embodiments, the seed material 119 is formed of and includes TiN, W, Mo, Ru, or Ti.

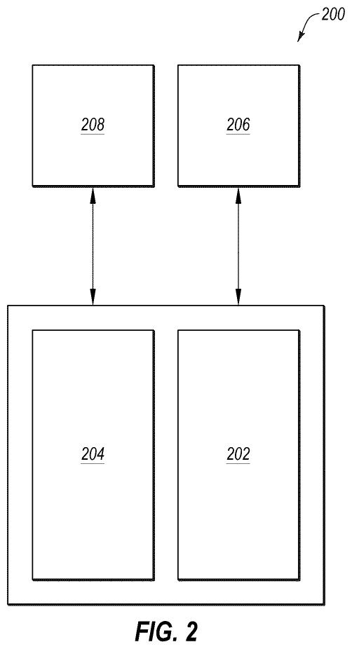

Referring to FIG. 1D-2, in another embodiment, the preliminary structures 127-2 are formed within the first trenches 115. The preliminary structures 127-2 may respectively include a sacrificial material 121. The sacrificial material 121 is configured to enable a digit line alignment material 118 (FIG. 1H) to grow on the sacrificial material 121 after the later removal of the base structure 102 (for the later formation of aligned digit line structures, as discussed hereinbelow). In some embodiments, the sacrificial material 121 is formed of and includes Si₃N₄ or SiO₂.

Referring to FIG. 1E, an insulative material 114 is formed on or over the preliminary structures 127 within the first trenches 115 (FIG. 1D). The insulative material 114 may substantially fill remaining (e.g., unfilled) portions of the first trenches 115 (FIG. 1D). In an embodiment, the insulative material 114 is a low-k dielectric material (e.g., a dielectric material having a dielectric constant (k) less than that of SiO₂), such as a carbon-doped dielectric oxide material. In an additional embodiment, the insulative material 114 is formed of and includes a dielectric nitride material, such as silicon nitride. The insulative material 114 has etch selectivity relative to the dielectric liner structures 117.

Still referring to FIG. 1E, in order to create the later-formed VCAD, additional trenches (e.g., y-axis trenches) may be formed to extend vertically into the semiconductor material 103 and the insulative material 114. The additional trenches may extend horizontally in parallel in the second direction (e.g., the Y-direction) perpendicular to the first direction (e.g., X-direction) in which the first trenches 115 (FIG. 1D) horizontally extend. The formation of the first trenches 115 (FIG. 1D) and the additional trenches effectuates the formation of semiconductor pillars 133 from the semiconductor lines 108 (FIG. 1D) of the semiconductor material 103. The semiconductor pillars 133 have side surfaces (e.g., sidewalls) defined by horizontal boundaries of the first trenches 115 (FIG. 1D) and the additional trenches. In some embodiments, the additional trenches are formed using etching processes (e.g., anisotropic etching processes) that selectively remove exposed portions of the semiconductor material 103 and the insulative material 114. The additional trenches have vertical depths (e.g., vertical heights in the Z-direction) shorter than the vertical depths of the first trenches 115. For example, bottoms of the first trenches 115 (FIG. 1D) may be adjacent to an upper surface of the insulative structure 106 of the first base structure 104, whereas bottoms of the additional trenches may vertically terminate above the upper surface of the insulative structure 106.

Still referring to FIG. 1E, word line structures 116, schematically represented by dashed rectangle since outside of the ZY-plane shown in FIG. 1E, may be formed within the additional trenches. For example, a dielectric liner 139 (FIG. 1R) (also referred to herein as a “gate dielectric material”) may be formed (e.g., conformally deposited) on exposed surfaces within the additional trenches, such as side surfaces of the semiconductor pillars 133 and the insulative material 114. The dielectric liner 139 may be formed of and include insulative material. In some embodiments, the dielectric liner is formed of and includes silicon dioxide. In some embodiments, the dielectric liner 139 is formed (e.g., conformally deposited) inside and outside of the additional trenches, and portions of the dielectric liner outside of the additional trenches are maintained. In additional embodiments, the dielectric liner 139 is formed (e.g., conformally deposited) inside and outside of the additional trenches, and then portions of the dielectric liner outside of the additional trenches are removed (e.g., by way of CMP) while additional portions of the dielectric liner within the additional trenches are maintained.

Following the formation of the dielectric liner 139, remaining portions of the additional trenches may be partially filled within a spacer material 138 (shown in FIG. 1R) (e.g., word line capping material). In one or more embodiments, the spacer material 138 is deposited within the additional trenches through a spin-on coating process. For instance, the spacer material 138 (FIG. 1R) may include a spin-on dielectric. Furthermore, subsequent to the spin-on coating process, the spacer material 138 (FIG. 1R) may be recessed (e.g., removed through an etching process (dry or wet etching process)) to leave only portions of the spacer material 138 (FIG. 1R) proximate the bottoms of the additional trenches. In some embodiments, the spacer material 138 is formed of nitride material. The spacer material 138 (FIG. 1R) may be substantially homogeneous, or the spacer material may be heterogeneous. The spacer material 138 (FIG. 1R) may, for example, be formed of and include a stack of at least two different dielectric materials. In another embodiment, the spacer material 138 is deposited within the additional trenches prior to the formation of the dielectric liner 139. The spacer material 138 is configured to position the subsequently formed word line structures 116 and back shield 116′ (e.g., back gate) at desired locations within the additional trenches. After the spacer material 138 is deposited the dielectric liner 139 (FIG. 1R) (also referred to herein as a “gate dielectric material”) is formed (e.g., conformally deposited) on exposed surfaces within the additional trenches, such as side surfaces of the semiconductor pillars 133 and the insulative material 114.

The degree to which the spacer material 138 (FIG. 1R) is recessed may serve to position the later-formed gate electrodes (e.g., word line structures 116) a desired distance from the boundary (e.g., interface) of the first doped region 109 and the undoped region 111 respective ones of the semiconductor pillars 133. For instance, the remaining portion of the spacer material 138 may space the later-formed word line structures 116 within a vertical span of the undoped region 111 and vertically offset from the boundary of the first doped region 109 and the undoped region 111. The remaining portion of the spacer material 138 may exhibit a vertical thickness within a range of from about 30 nm to about 60 nm. For instance, the spacer material 138 may be etched to have a vertical thickness of about 45 nm.

Still referring to FIG. 1E, following the formation of the spacer material 138 (FIG. 1R), gate electrode material may be formed on or over the spacer material 138 (FIG. 1R) within the additional trenches, and then portions of the gate electrode material may be removed (e.g., anisotropic ally etched) to form the word line structures 116. The word line structures 116 may respectively vertically overlap the undoped regions 111 (e.g., channel regions) of the semiconductor pillars 133. The gate electrode material (and, hence, the word line structures 116) may be formed of and include conductive material, such as one or more of tungsten (W), ruthenium (Ru), molybdenum (Mo), titanium (Ti), alloys thereof, and nitrides thereof. The previously formed dielectric liner serves as a gate dielectric intervening between the word line structures.

The formation of the semiconductor pillars 133, the dielectric liner 139 (FIG. 1R), and the word line structures 116 effectuates the formation of vertical channel access devices (VCADs) 134. The semiconductor pillars 133 (including the first doped regions 109, the undoped regions 111, and the second doped regions 113 thereof), the dielectric liner 139 (FIG. 1R), and the word line structures 116 may together form the vertical channel access devices 134. The vertical channel access devices 134 may individually include a channel region comprising the undoped region 111 of an individual semiconductor pillar 133, a drain region comprising the first doped region 109 of the semiconductor pillar 133, and a source region comprising the second doped region 113 of the semiconductor pillar 133. In addition, the vertical channel access device 134 may include a gate electrode comprising a portion of an individual word line structure 116, and a gate dielectric material comprising the dielectric liner 139 (FIG. 1R). Different portions of an individual word line structure 116 form gates for multiple vertical channel access devices 134.

Referring to FIG. 1F, following the formation of the vertical channel access devices 134, the first assembly 101 is vertically inverted (e.g., flipped) so that the base structure 102 (e.g., the first base structure 104 and the insulative structure 106) is positioned vertically above the vertical channel access devices 134.

Referring to FIG. 1G, the base structure 102 (e.g., the first base structure 104 and the insulative structure 106) is removed. The base structure 102 (e.g., carrier wafer) may be removed by planarization, a cutting process, or other conventional processes as would be appreciated by one of ordinary skill in the art having the benefit of this disclosure. As shown in FIG. 1G, with respect to the embodiment shown in FIG. 1D, the removal of the base structure 102 may expose surfaces of the conductive material 112 of the preliminary structures 127 previously deposited within the first trenches 115 (FIG. 1D), as well as surfaces of the first doped regions 109 of the semiconductor pillars 133. With respect to the embodiment shown in FIG. 1D-1, the removal of the base structure 102 may expose surfaces of the seed material 119 of the preliminary structures 127-1 (FIG. 1D-1). With respect to the embodiment shown in FIG. 1D-2, the removal of the base structure 102 may expose surfaces of the sacrificial material 121 of the preliminary structures 127-2 (FIG. 1D-2). The removal of the base structure 102 may expose surfaces of the dielectric liner structures 117.

Referring to FIG. 1H, a digit line alignment material 118 is grown on the exposed surfaces of the conductive material 112 of the preliminary structures 127 (or the seed material 119 (FIG. 1D-1) of the preliminary structures 127-1 (FIG. 1D-1); or the sacrificial material 121 (FIG. 1D-2) of the of the preliminary structures 127-2 (FIG. 1D-2) to form digit line alignment structures 142. In an embodiment, a horizontal width (e.g., in the Y-direction) of digit line alignment structures 142 corresponds to the horizontal width (e.g., in the Y-direction) of a respective one of the preliminary structures 127 (or a respective one of the preliminary structures 127-1 (FIG. 1D-1); or a respective one of the preliminary structures 127-2 (FIG. 1D-2)) vertically thereunder (e.g., in the Z-direction) because the digit line alignment material 118 is grown thereon. In some embodiments, a vertical height (e.g., in the Z-direction) of the digit line alignment structures 142 is within a range of from 5 nm to 50 nm.

In one embodiment, the digit line alignment material 118 of the digit line alignment structures 142 comprises conductive material, such as conductive material including one or more of Ti, W, Mo, and Ru. In some embodiments, the digit line alignment material 118 includes a metal nitride material (e.g., titanium nitride, tungsten nitride). In additional embodiments, the digit line alignment material 118 includes a metal silicide material (e.g., titanium silicide, tungsten silicide). In additional embodiments, such as embodiments wherein the digit line alignment material 118 is later substantially removed, the digit line alignment material 118 may be formed of and include one or more of insulative material and semiconductor material.

Referring to FIG. 1I, a liner material 120 is formed (e.g., conformally deposited) on the exposed surfaces of the digit line alignment structures 142, as well as on exposed surfaces of the dielectric liner structures 117 and the second doped regions 113 of the semiconductor pillars 133 of the VCADs 134. In one embodiment, a material composition of the liner material 120 differs from that of the dielectric liner structures 117. In another embodiment, a material composition of the liner material 120 is substantially the same as that of the dielectric liner structures 117. The liner material 120 may be formed of and include insulative material, such as dielectric nitride material (e.g., silicon nitride).

In an embodiment, a thickness of the liner material 120 in a direction (e.g., the Y-direction) normal to sidewalls of the digit line alignment structures 142 is substantially the same as the thickness (e.g., in the Y-direction) of a respective one of the dielectric liner structures 117 vertically under and in physical contact therewith. In another embodiment, the of the liner material 120 is less than the thickness of the dielectric liner structures 117. In yet another embodiment, the thickness of the liner material 120 is greater than the thickness of the dielectric liner structures 117.

Referring to FIG. 1J, portions of the liner material 120 (FIG. 1I) are removed (e.g., etched away) to form liner structures 123 and recesses 122 (e.g., openings). Portions of the liner material 120 (FIG. 1I) remaining on sidewalls of the digit line alignment structures 142 may form the liner structures 123. The recesses 122 may be horizontally interposed, in the Y-direction, between neighboring liner structures 123 and are configured to facilitate self-alignment digit line structures 140 (FIG. 1K) relative to the semiconductor pillars 133 of the VCADs 134, as discussed hereinbelow. An interface 137 is present between surfaces of the dielectric liner structures 117 and the liner structures 123, even if the dielectric liner structures 117 and the liner structures 123 have substantially the same material composition as one another. The growth of the digit line alignment material 118, the conformal deposition of the liner material 120 (FIG. 1I), and the material removal (e.g., etching) process to form the liner structures 123 ensures that the recesses 122 are configured to facilitate desired horizontal self-alignment of subsequently formed digit line structures with the semiconductor pillars 133 of the VCADs 134.

Referring to FIG. 1J-1, in additional embodiment, portions of the liner material 120 (FIG. 1I) are removed (e.g., etched away) to form liner structures 123′ and recesses 122′ (e.g., openings). Portions of the liner material 120 (FIG. 1I) remaining on sidewalls of the digit line alignment structures 142 may form the liner structures 123′. The recesses 122′ may be horizontally interposed, in the Y-direction, between neighboring liner structures 123′ and are configured to facilitate self-alignment digit line structures 140′ (FIG. 1P-1) relative to the semiconductor pillars 133 of the VCADs 134, as discussed hereinbelow. An interface 137 is present between surfaces of the dielectric liner structures 117 and the liner structures 123′, even if the dielectric liner structures 117 and the liner structures 123′ have substantially the same material composition as one another. The growth of the digit line alignment material 118, the conformal deposition of the liner material 120 (FIG. 1I), and the material removal (e.g., etching) process to form the liner structures 123′ ensures that the recesses 122′ are configured to facilitate desired horizontal self-alignment of subsequently formed digit line structures 140′ (FIG. 1P-1) with the semiconductor pillars 133 of the VCADs 134. The cross-sectional thickness of the liner structures 123′ is greater than the cross-sectional thickness of the dielectric liner structures 117 of the semiconductor pillars 133. In other words, the thickness (e.g., in the Y-direction) of the liner structures 123′ is greater than the thickness (e.g., in the Y-direction) of the dielectric liner structures 117 of the semiconductor pillars 133. Due to the different thicknesses of the liner structures 123′ and the dielectric liner structures 117, a centerline 123′-1 of the liner structures 123′ is offset from a centerline 117-1 of the dielectric liner structures 117. This results in recesses 122′ having a smaller width (e.g., in the Y-direction) than the corresponding recesses 122 shown in FIG. 1J. Thus, the subsequently formed digit line structures 140′ (FIG. 1P-1) have a cross-sectional thickness (e.g., in the Y-direction) that is smaller than the cross-sectional thickness (e.g., in the Y-direction) of the drain region (e.g., the first doped region 109) of the adjacent semiconductor pillar 133. Nevertheless, the recesses 122′ defined by liner structures 123′ are configured to align the later formed digit line structures 140′ (FIG. 1P-1) with the drain region (e.g., first doped region 109) of the semiconductor pillars 133 of the VCADs 134 as discussed herein. In another embodiment, the thickness (e.g., in the Y-direction) of the liner structures 123′ is smaller than the thickness (e.g., in the Y-direction) of the dielectric liner structures 117 of the semiconductor pillars 133 resulting in recesses 122′ having a greater width (e.g., in the Y-direction) than the recesses 122 shown in FIG. 1J.

Referring to FIG. 1K, conductive material (e.g., digit line material) 124 is formed within the recesses 122 (FIG. 1J) (or the recesses 122′ (FIG. 1J-1)) to form digit line structures 140. The recesses 122 are configured to facilitate self-alignment of a horizontal first centerline 128, in the Y-direction, of respective ones of the digit line structures 140 with horizontal second centerlines 130 first doped region 109 of respective ones of the semiconductor pillars 133 of the VCADs 134. The digit line structures 140 may respectively be formed to vertically overlie (e.g., in the Z-direction), horizontally overlap (e.g., in the Y-direction), and physically contact with the semiconductor pillars 133 of a group (e.g., a row, a column) of the VCADs 134. The self-alignment of the digit line structures (e.g., conductive structure 124) may improve the functioning of a memory device utilizing such structure. Misalignment between digit line structures (e.g., conductive structure 124) and corresponding drain regions (e.g., first doped regions 109) may result in the non-efficient operation, or even non-functioning, of a memory device utilizing the microelectronic device structure 100.

Referring to FIG. 1L, after the formation of the digit line structures 140, portions of the digit line structures 140 are selectively exhumed (e.g., selectively etched) to form recesses 144.

Referring to FIG. 1M, a dielectric capping material 146 is formed (e.g., conformally deposited) on the exposed surfaces of the digit line alignment structures 142, the exposed surfaces of the liner structures 123, and the exposed surfaces of digit line structures 140. The dielectric capping material 146 fills in the recesses 144 (FIG. 1L). The dielectric capping material 146 may be formed of and include insulative material. In one embodiment, the dielectric material is dielectric oxide material (e.g., SiO₂).

Referring to FIG. 1N, a planarization process is applied to the top surface (e.g., in the Z-direction) of the microelectronic device structure 100. The planarization process removes a portion of the dielectric capping material 146 to form dielectric capping structures 149. The planarization process may also remove upper portions of the digit line alignment structures 142 and the liner structures 123. Following the planarization process upper surfaces of the dielectric capping structures 149, the digit line alignment structures 142, and the liner structures 123 may be substantially coplanar with one another.

Referring to FIG. 1N-1, in additional embodiments wherein the digit line alignment material 118 was formed on the sacrificial material 121 (FIG. 1D-2), the planarization process is applied to the top surface (e.g., in the Z-direction) of the microelectronic device structure 100, and removes a portion of the dielectric capping material 146 to form the dielectric capping structures 149. The planarization process may also remove upper portions of the digit line alignment structures 142 and the liner structures 123. Following the planarization process upper surfaces of the dielectric capping structures 149, the digit line alignment structures 142, and the liner structures 123 may be substantially coplanar with one another. As discussed above, the planarization process removes a portion of the top surfaces of the digit line alignment structures 142, liner structures 123, and a portion of the dielectric capping material 146 to form dielectric capping structures 149. In this embodiment, the digit line alignment material 118 and the sacrificial material 121 may later be removed (e.g., exhumed) from the microelectronic device structure 100 as discussed below regarding FIG. 1O-1.

Referring to FIG. 1O, in some embodiments, the digit line alignment structures 142 (FIG. 1N) are selectively exhumed (e.g., selectively etched) to form recesses 131. If formed, the recesses 131 may expose upper surfaces of the preliminary structures 127 (or the preliminary structures 127-1 (FIG. 1D-1)). In additional embodiments, such as some embodiments wherein the digit line alignment structures 142 are formed of include conductive material (e.g., conductive material having a material composition substantially the same as that of conductive material 112 of the preliminary structures 127), the digit line alignment structures 142 may be substantially maintained.

Referring to FIG. 1O-1, in additional embodiments wherein the digit line alignment structures 142 (FIG. 1N) are formed on the preliminary structures 127-1 (FIG. 1D-2), the digit line alignment structures 142 and the underlying preliminary structures 127-1 (FIG. 1D-2) are selectively exhumed (e.g., selectively etched) to form recesses 131′. If formed, the recesses 131′ may expose upper surfaces of the previously formed insulative material 114 (FIG. 1E).

Referring to FIG. 1P, structures 143 are formed within the recesses 131 (FIG. 1O) created by the removal of the digit line alignment structure 142 (FIG. 1N). The structures 143 may be formed by the deposition of conductive material 112′ within the recesses 131. The structures 143 and the preliminary structures 127 may, in combination, form digit line shield structures 132. The formation of the structures 143 on the preliminary structures 127 may create discernable interfaces 126 even in the instance that the preliminary structures 127 and the structures 143 are comprised of the same conductive material.

Still referring to FIG. 1P, each of the digit line structures 140 is aligned with the semiconductor pillar 133 of an adjacent VCAD 134 as illustrated by the substantial alignment of the first centerline 128 of the digit lines structures with the second centerline 130 of the drain region (e.g., first doped region 109) of the semiconductor pillar 133. The alignment ensures efficient coupling of the digit line structures 140 with the VCADs 134 of the microelectronic device structure 100. In the event the widths (e.g., in the Y-direction) of the liner structure 123 and dielectric liner structures 117 are substantially equal (as shown in FIG. 1J), a width 129 (e.g., in the Y-direction) of the digit line structures 140 will substantially correspond to a width 135 (e.g., in the Y-direction) of the semiconductor pillar 133 of the adjacent VCAD 134.

Referring to FIG. 1P-1, in additional embodiments, each of the digit line structures 140 is aligned with the semiconductor pillar 133 of an adjacent VCAD 134 as illustrated by the substantial alignment of the first centerline 128 of the digit lines structures with the second centerline 130 of the drain region (e.g., first doped region 109) of the semiconductor pillar 133. In the event the widths (e.g., in the Y-direction) of the liner structure 123 and dielectric liner structures 117 are not substantially equal (as shown in FIG. 1J-1), a width 129′ (e.g., in the Y-direction) of the digit line structures 140 will differ to a width 133′ (e.g., in the Y-direction) of the semiconductor pillar 133 of the adjacent VCAD 134. The process disclosed herein provides for the self-alignment of the digit line structures 140 with the semiconductor pillar 133 of an adjacent VCAD 134 irrespective of the width (e.g., in the Y-direction) to ensure intended performance of the VCAD 134.

Referring to FIG. 1P-2, in further embodiments, conductive material 112′′ is deposited within the recesses 131′ (FIG. 1O-1) created by the removal of the digit line alignment structure 142 and the preliminary structure 127-2 (FIG. 1N-1). The deposition of conductive material 112′′ forms digit line shield structures 132. The deposition of conductive material 112′′ on previously deposited insulative material 114 creates an interface 126′ between the digit line shield structures 132 and the insulative material 114.

Referring to FIG. 1Q, following the processing stage of FIG. 1P, conductive material may be deposited on an exposed top surface (e.g., in the Z-direction) of the microelectronic device structure 100 to form a shield plate 148. The shield plate 148 may, for example, continuously horizontally extend (e.g., in the X-direction, in the Y-direction) over and substantially cover top surfaces of the structures 143, the liner structures 123, and the dielectric capping structures 149. The previously formed dielectric capping structures 149 (FIG. 1N) are configured to electrically isolate the digit line structures 140 from the shield plate 148.

Referring next to FIG. 1R, further processing may be effectuated on or with the microelectronic device structure 100 following the process stage described with reference to FIG. 1S to form a second assembly 147 including the microelectronic device structure 100 and coupled with a multi-storage node structure 160. The digit line structures 140 vertically overlie and are coupled to the vertical channel access devices 134 of the microelectronic device structure 100, and the multi-storage node structure 160 may be vertically underlie and include storage node devices 166 coupled to the vertical channel access devices 134 of the microelectronic device structure 100. Various features of the microelectronic device (e.g., the second assembly 147) are described in further detail below.

Various structures may be formed above the digit line structures 140, between the digit line structures 140 and an insulative material 152 thereover, as would be appreciated by one of ordinary skill in the art having the benefit of this disclosure. The insulative material 152 may be formed to have an at least substantially planar upper surface 154. In one or more embodiments, the insulative material 152 is formed of and includes a dielectric oxide material, such as SiOₓ (e.g., SiO₂). The insulative material 152 may be substantially homogeneous, or the insulative material 152 may be heterogeneous. As is discussed in greater detail below with reference to FIG. 1R, in some embodiments, the insulative material 152 of the second assembly 147 is utilized to bond the second assembly 147 to another structure (e.g., a control circuitry structure) by way of dielectric-to-dielectric bonding, such as an oxide-to-oxide bonding.

Still referring to FIG. 1R, the second assembly 147 may be formed to further include redistribution material (RDM) structures 145 that may, for example, facilitate a horizontal arrangement (e.g., a hexagonal close packed arrangement) of the storage node devices 166 (e.g., capacitors) (described in further detail below) of the multi-storage node structure 160 that is different than a horizontal arrangement of the semiconductor pillars 133 of the vertical channel access devices 134 of the microelectronic device structure 100, while still coupling the vertical channel access devices 134 to the storage node devices 166. The RDM structures 145 may be formed of and include conductive material, such as one or more of W, Ru, Mo, and TiN_{y}.

As previously mentioned, the multi-storage node structure 160 includes multiple storage node devices 166 (e.g., capacitors) may be formed on or over the RDM structures 145 to form a second assembly 147, the second assembly 147 including the first assembly 101 and the multi-storage node structure 160. The storage node devices 166 may be in electrical contact with the RDM structures 145, and, hence, with the vertical channel access devices 134. The storage node devices 166 may be coupled to the vertical channel access devices 134 by way of at least the RDM structures 145 to form memory cells 141 (e.g., DRAM cells).

Each memory cell 141 may individually include one of the vertical channel access devices 134, one of the storage node devices 166, and one of the RDM structures 145 extending from and between the one of the vertical channel access devices 134 and the one of the storage node devices 166. The storage node devices 166 may individually be formed and configured to store a charge representative of a programmable logic state of the memory cell 141 including the storage node device 166.

In some embodiments, the storage node devices 166 include capacitors. During use and operation, a charged capacitor may represent a first logic state, such as a logic 1; and an uncharged capacitor may represent a second logic state, such as a logic 0. Each of the storage node devices 166 may, for example, be formed to include a first electrode 162 (e.g., a bottom electrode), a second electrode 163 (e.g., a top electrode), and a dielectric material 164 between the first electrode 162 and the second electrode 163. For instance, each of the storage node devices 166 may include a metal-insulator-metal (MIM) capacitor. As another example, each of the storage node devices 166 may include a metal-insulator-semiconductor (MIS) capacitor. The collection of memory cells 141 may form a memory array.

The multi-storage node structure 160 may further include a conductive material 161 formed between neighboring storage node devices 166. The conductive material 161 may substantially cover and surround the storage node devices 166. The second electrode 163 of the storage node devices 166 may be operatively positioned (e.g., embedded) within the conductive material 161. The conductive material 161 may include any of the conductive materials described herein. For instance, the conductive material 161 may include polysilicon or conductively doped silicon germanium (SiGe).

Still referring to FIG. 1R, a cell plate 165 may be formed on and over the multi-storage node structure 160 of the second assembly 147. For instance, the cell plate 165 may be formed on and over the conductive material 161. The cell plate 165 may include any of the conductive materials described herein. For instance, the cell plate 165 may include a tungsten (W). A carrier structure 169 (e.g., a carrier wafer) may be formed on or attached to the multi-storage node structure 160 of the second assembly 147. The carrier structure 169 may include a second base structure 168 and an insulative material 167 on or over the second base structure 168. In some embodiments, the insulative material 167 is formed of and includes a dielectric oxide material, such as SiOₓ (e.g., SiO₂). The insulative material 167 may be substantially homogeneous, or the insulative material 167 may be heterogeneous.

The second base structure 168 may include a base material or construction upon which additional features (e.g., materials, structures, devices) of the formed. In some embodiments, the second base structure 168 comprises a wafer. The second base structure 168 may be formed of and include one or more of semiconductor material (e.g., one or more of a silicon material, such monocrystalline silicon or polycrystalline silicon (also referred to herein as “polysilicon”); silicon-germanium; germanium; gallium arsenide; a gallium nitride; gallium phosphide; indium phosphide; indium gallium nitride; and aluminum gallium nitride), a base semiconductor material on a supporting structure, glass material one or more of borosilicate glass (BSP), phosphosilicate glass (PSG), fluorosilicate glass (FSG), borophosphosilicate glass (BPSG), aluminosilicate glass, an alkaline earth boro-aluminosilicate glass, quartz, titania silicate glass, and soda-lime glass), and ceramic material (e.g., one or more of poly-aluminum nitride (p-AlN), silicon on poly-aluminum nitride (SOPAN), aluminum nitride (AlN), aluminum oxide (e.g., sapphire; α—Al₂O₃), and silicon carbide). By way of non-limiting example, the second base structure 168 may comprise a semiconductor wafer (e.g., a silicon wafer), a glass wafer, or a ceramic wafer. The second base structure 168 may include one or more materials, structures, and/or regions formed therein and/or thereon.

Referring next to FIG. 1S, a control circuitry structure 180 may be attached (e.g., bonded, such as at least dielectric-to-dielectric bonded) to the second assembly 147 to form a microelectronic device 170 (e.g., a memory device, such as a DRAM device) of the disclosure. Circuity of the control circuitry structure 180 may be coupled to various features (e.g., the digit line structures 140, the memory cells 141) of the second assembly 147, as indicated in FIG. 1S by a dashed line 182.

In some implementations, the control circuitry structure 180 includes complementary metal-oxide-semiconductor (CMOS) circuitry. As a non-limiting example, the control circuitry structure 180 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., main word line drivers, sub word line drivers (SWD)), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, array multiplexers (MUX), error checking and correction (ECC) devices, self-refresh/wear leveling devices, and other chip/deck control circuitry.

In accordance with embodiments of the disclosure, a microelectronic device includes a vertical channel access device (VCAD). The VCAD includes a semiconductor pillar that includes a first doped region, a channel region vertically above the first doped region, and a second doped region vertically above the channel region. The VCAD includes a gate electrode horizontally offset from the semiconductor pillar in a first direction and vertically overlapping the channel region of the semiconductor pillar. The VCAD includes a gate dielectric material horizontally interposed between the gate electrode and the semiconductor pillar in the first direction.

The microelectronic device includes a first liner structure extending in the first direction and horizontally neighboring the semiconductor pillar in a second direction orthogonal to the first direction. The microelectronic device includes a second liner structure vertically offset from and in physical contact with the first liner structure, the second liner structure horizontally overlapping the first liner structure in the second direction. The microelectronic device includes a digit line structure vertically offset from and substantially horizontally centered in the second direction about the semiconductor pillar of the VCAD, the digit line structure in physical contact with each of the second liner structure and the first doped region of the semiconductor pillar of the VCAD.

In accordance with embodiments of the disclosure, a method of forming a microelectronic device includes forming an assembly comprising semiconductor lines horizontally separated from one another in a first direction by trenches horizontally extending in a second direction orthogonal to the first direction. The method includes forming first liner structures within the trenches and on side surfaces the semiconductor lines. The method includes forming preliminary structures within the trenches and on outer side surfaces of the first liner structures. The method includes removing portions of the semiconductor lines to form semiconductor pillars and additional trenches extending in the second direction. The method includes forming word line structures within the additional trenches. The method includes after forming the word line structures, vertically inverting the assembly and forming digit line alignment structures on the preliminary structures. The method includes forming second liner structures on side surfaces of the digit line alignment structures. The method includes forming digit line structures horizontally neighboring the second liner structures in the first direction and horizontally extending in the horizontally extending in a second direction, each of the digit line structures substantially horizontally aligned with a group of the semiconductor pillars in the first direction.

In accordance with embodiments of the disclosure, a memory device includes a memory cell including a vertical channel access device (VCAD). The VCAD includes a channel region vertically interposed between two source/drain regions. The VCAD includes a gate electrode horizontally offset in a first direction from the channel region and vertically overlapping the channel region. The VCAD includes a gate dielectric material horizontally interposed between the channel region and the gate electrode in the first direction and vertically overlapping the channel region and at least part of the two source/drain regions. The memory cell includes a storage node device vertically offset from and coupled to the vertical channel access device. The memory device includes a first liner structure horizontally extending in the first direction and horizontally neighboring the channel region in the second direction orthogonal to the first direction. The memory device includes a second liner structure vertically offset from and in physical contact with the first liner structure, the second liner structure horizontally overlapping the first liner structure in the second direction. The memory device includes a digit line structure vertically offset from and substantially horizontally centered in the second direction about one of the two source/drain regions of the VCAD, the digit line structure in physical contact with the second liner structure and the one of the two source/drain regions of the VCAD.

Microelectronic devices (e.g., the microelectronic device 170 (FIG. 1S)) in accordance with embodiments of the disclosure may be used in embodiments of electronic systems of the disclosure. For example, FIG. 2 is a block diagram illustrating an electronic system 200 according to embodiments of disclosure. The electronic system 200 may comprise, for example, a computer or computer hardware component, a server or other networking hardware component, a cellular telephone, a digital camera, a personal digital assistant (PDA), portable media (e.g., music) material, a Wi-Fi or cellular-enabled tablet such as, for example, an iPAD® or SURFACE® tablet, an electronic book, a navigation device, etc. The electronic system 200 includes at least one memory device 202. The memory device 202 may comprise, for example, a microelectronic device (e.g., the microelectronic device 170 (FIG. 1S)) previously described herein. The electronic system 200 may further include at least one electronic signal processor device 204 (often referred to as a “microprocessor”). The electronic signal processor device 204 may, optionally, comprise a microelectronic device (e.g., the microelectronic device 170 (FIG. 1S)) previously described herein. While the memory device 202 and the electronic signal processor device 204 are depicted as two (2) separate devices in FIG. 2, in additional embodiments, a single (e.g., only one) memory/processor device having the functionalities of the memory device 202 and the electronic signal processor device 204 is included in the electronic system 200. In such embodiments, the memory/processor device may include a microelectronic device (e.g., the microelectronic device 170 (FIG. 1S)) previously described herein. The electronic system 200 may further include one or more input devices 206 for inputting information into the electronic system 200 by a user, such as, for example, a mouse or other pointing device, a keyboard, a touchpad, a button, or a control panel. The electronic system 200 may further include one or more output devices 208 for outputting information (e.g., visual or audio output) to a user such as, for example, a monitor, a display, a printer, an audio output jack, a speaker, etc. In some embodiments, the input device 206 and the output device 208 comprise a single touchscreen device that can be used both to input information to the electronic system 200 and to output visual information to a user. The input device 206 and the output device 208 may communicate electrically with one or more of the memory device 202 and the electronic signal processor device 204.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure. Various modifications of the disclosure, in addition to those shown and described herein, such as alternate useful combinations of the elements and features described will become apparent to those skilled in the art from the description. Such modifications and embodiments also fall within the scope of the appended claims and equivalents.

What is claimed is:

1. A microelectronic device, comprising:
a vertical channel access device (VCAD) comprising:
a semiconductor pillar comprising:
a first doped region;
a channel region vertically above the first doped region; and
a second doped region vertically above the channel region; and
a gate electrode horizontally offset from the semiconductor pillar in a first direction and vertically overlapping the channel region of the semiconductor pillar; and
a gate dielectric material horizontally interposed between the gate electrode and the semiconductor pillar in the first direction;
a first liner structure horizontally extending in the first direction and horizontally neighboring the semiconductor pillar in a second direction orthogonal to the first direction;
a second liner structure vertically offset from and in physical contact with the first liner structure, the second liner structure horizontally overlapping the first liner structure in the second direction; and
a digit line structure vertically offset from and substantially horizontally centered in the second direction about the semiconductor pillar of the VCAD, the digit line structure in physical contact with each of the second liner structure and the first doped region of the semiconductor pillar of the VCAD.

2. The microelectronic device of claim 1, further comprising a shield structure horizontally neighboring, in the second direction, each of the first liner structure and the second liner structure.

3. The microelectronic device of claim 2, wherein the second liner structure comprises:
an upper surface substantially coplanar with a top surface of the shield structure; and
a lower surface vertically offset from a bottom surface of the shield structure.

4. The microelectronic device of claim 3, wherein the bottom surface of the bottom surface of the shield structure is within a vertical extent of the channel region of the semiconductor pillar of the VCAD.

5. The microelectronic device of claim 3, wherein the digit line structure comprises:
an upper boundary substantially coplanar with the upper surface of the second liner structure; and
a lower boundary substantially coplanar with the lower surface of the second liner structure.

6. The microelectronic device of claim 3, wherein the shield structure is a substantially monolithic structure comprising conductive material continuously extending from and between the top surface and the bottom surface thereof.

7. The microelectronic device of claim 1, wherein:
horizontal widths, in the second direction, of the first liner structure and the second liner structure are substantially equal to one another; and
the second liner structure is substantially centered about the first liner structure in the second direction.

8. The microelectronic device of claim 7, wherein additional horizontal widths, in the second direction, of the digit line structure and the semiconductor pillar of the VCAD are substantially equal to one another.

9. The microelectronic device of claim 1, wherein:
horizontal widths, in the second direction, of the first liner structure and the second liner structure are different than one another; and
horizontal centerlines, in the second direction, of the first liner structure and the second liner structure are offset from one another.

10. The microelectronic device of claim 9, wherein an additional horizontal width of the digit line structure in the second direction is less than a further horizontal width semiconductor pillar of the VCAD in the second direction.

11. A method of forming a microelectronic device, comprising:
forming an assembly comprising semiconductor lines horizontally separated from one another in a first direction by trenches horizontally extending in a second direction orthogonal to the first direction;
forming first liner structures within the trenches and on side surfaces the semiconductor lines;
forming preliminary structures within the trenches and on outer side surfaces of the first liner structures;
removing portions of the semiconductor lines to form semiconductor pillars and additional trenches extending in the second direction;
forming word line structures within the additional trenches;
after forming the word line structures, vertically inverting the assembly and growing digit line alignment structures on the preliminary structures;
forming second liner structures on side surfaces of the digit line alignment structures; and
forming digit line structures horizontally neighboring the second liner structures in the first direction and horizontally extending in a second direction, each of the digit line structures substantially horizontally aligned with a group of the semiconductor pillars in the first direction.

12. The method of claim 11, further comprising:
removing the digit line alignment structures after forming the digit line structures; and
forming conductive material on the preliminary structures to form linear shield structures, each of the linear shield structures comprising:
a lower portion comprising a remainder of a respective one of the preliminary structures; and
an upper portion comprising the conductive material.

13. The method of claim 12, further comprising selecting the conductive material to have substantially a same material composition as that of the preliminary structures.

14. The method of claim 13, further comprising performing a material removal process to make upper surfaces of the linear shield structures, the digit line structures, and the second liner structures substantially coplanar with one another.

15. The method of claim 11, further comprising:
after forming the digit line structures, removing the digit line alignment structures and the and the preliminary structures to form additional trenches; and
forming linear shield structures within the additional trenches.

16. The method of claim 11, wherein forming preliminary structures within the trenches comprises forming the preliminary structures to respectively comprise a seed material on a conductive material, the seed material configured to effectuate the growth of the digit line alignment structures.

17. The method of claim 11, further comprising forming the digit line structures to individually have a horizontal width in the first direction substantially equal to a horizontal width in the first direction of a respective one of the semiconductor pillars in physical contact therewith.

18. A memory device, comprising:
a memory cell comprising:
a vertical channel access device (VCAD) comprising:
a channel region vertically interposed between two source/drain regions;
a gate electrode horizontally offset in a first direction from the channel region and vertically overlapping the channel region; and
a gate dielectric material horizontally interposed between the channel region and the gate electrode in the first direction and vertically overlapping the channel region and at least part of the two source/drain regions;
a storage node device vertically offset from and coupled to the vertical channel access device;
a first liner structure horizontally extending in the first direction and horizontally neighboring the channel region in a second direction orthogonal to the first direction;
a second liner structure vertically offset from and in physical contact with the first liner structure, the second liner structure horizontally overlapping the first liner structure in the second direction; and
a digit line structure vertically offset from and substantially horizontally centered in the second direction about one of the two source/drain regions of the VCAD, the digit line structure in physical contact with the second liner structure and the one of the two source/drain regions of the VCAD.

19. The memory device of claim 18, further comprising a shield structure horizontally neighboring, in the second direction, each of the first liner structure and the second liner structure.

20. The memory device of claim 18, wherein the memory cell comprises a dynamic random-access memory (DRAM) cell.
